(19) United States
(12) Patent Application Publication
(10) Pub. No.: US 2008/0098659 A1
(43) Pub. Date: May 1, 2008

(54) Methods for securing individual abrasive particles to a substrate in a predetermined pattern

(76) Inventor: Chien-Min Sung, Tansui (TW)

Correspondence Address: THORPE NORTH & WESTERN, LLP., P.O. Box 1219, SANDY, UT, 84091-1219, US

(21) Appl. No.: 11/588,839

(22) Filed: Oct. 26, 2006

(51) Int. Cl. B05D 5/00; C30B 9/00; B01J 3/06; B24D 11/00

(52) U.S. Cl. 51/293; 423/446; 117/79; 117/929; 427/197; 427/198; 451/529; 51/307; 51/309; 51/298; 51/295

(57) ABSTRACT

A method for temporarily securing superabrasive particles to a substrate such as a tool substrate or a growth precursor and articles formed therefrom are provided. The method can include applying an array of adhesive droplets onto at least a portion of a substrate in accordance with a predetermined pattern. The pattern may be uniform grid equally spacing each adhesive droplet. The adhesive droplets can be suitable to each secure only a single superabrasive particle. The method may further include adhering a single superabrasive particle to each adhesive droplet. As a result of the method can yield a tool substrate and grow precursor having enhance particle growth and wear properties.

### FIELD OF THE INVENTION

The present invention relates generally to methods for securing abrasive particles to a substrate in preparation for further use of such particles. Accordingly, the present invention involves the fields of chemistry, metallurgy, and materials science.

### BACKGROUND OF THE INVENTION

Abrasive particles, including superabrasives particles, such as diamond and cubic boron nitride (cBN) have found widespread use as in a variety of abrading, polishing and cutting applications. Common tools which incorporate abrasive particles include cutting tools, drill bits, circular saws, grinding wheels, lapping belts, polishing pads, and the like.

Often times the superabrasive particles used in such tools are synthetically formed under ultrahigh pressure, e.g., about 5.5 GPa and high temperature, e.g., 1300° C. Diamond particles, in particular, can be grown by converting graphite to diamond under catalytic action of a molten metal. The molten metal also serves as a solvent for carbon. Typical catalysts used to synthesize diamond include iron, nickel, cobalt, manganese or their alloys. The growth rate of diamond is controlled by pressure and temperature. Typically, the lower the over-pressure required to make diamond stable and/or the lower the over-temperature needed to melt the catalyst metal, the slower the growth rate. For example, to grow saw grits in a molten alloy of iron and nickel of Invar composition (Fe65-Ni35), the pressure is about 5.2 GPa and temperature is about 1270° C.

One major factor to consider in superabrasive particle synthesis of high grade particles is selecting processing conditions that cause nearly uniform and simultaneous nucleation of superabrasive particles. Random nucleation methods allow some regions of raw materials to be wasted while other regions are densely packed with particles having a high percentage of defects. As a result, the volume efficiency of a typical reaction cell is generally less than 2 to 3 carats per cubic centimeter. This marginal yield still wastes large amounts of raw materials, reduces production efficiencies, and leaves considerable room for improvement.

Once the superabrasive particles have been formed, they may be used in the fabrication of a superabrasive tool. A typical superabrasive tool, such as a diamond saw blade, is manufactured by mixing diamond particles (e.g., 40/50 U.S. mesh saw grit) with a suitable metal support matrix powder (e.g., cobalt powder of 1.5 micrometer in size). The mixture is then compressed in a mold to form the right shape (e.g., a saw segment). This “green” form of the tool is then consolidated by sintering at a temperature between 700-1200° C. to form a single body with a plurality of abrasive particles disposed therein. Finally, the consolidated body is attached (e.g., by traditional brazing or soldering) to a tool body; such as the round blade of a saw, to form the final product.

The distance between superabrasive particles in a tool determines the work load each particle will perform. Improper spacing of the superabrasive particles typically leads to premature failure of the abrasive surface or structure. Thus, if the superabrasive particles are too close to one another, some of the particles are redundant and provide little or no assistance in cutting or grinding. In addition, excess particles add to the expense of production due the high cost of diamond and cubic boron nitride. Moreover, these non-performing particles can block the passage of debris, thereby reducing the cutting efficiency. Thus, having abrasive particles disposed too close to one another adds to the cost, while decreasing the service life of the tool.

As a result of the above-stated issues, both with respect to superabrasive particle synthesis and tool performance, a number of attempts have been made to place and hold superabrasive particles according to a desired pattern on a substrate preparatory to either diamond synthesis or tool fabrication. Many of these processes involve application of an adhesive or other fixing material onto a substantial portion of a substrate followed by placement of superabrasive particles onto the adhesive. In order to effect patterned placement of the superabrasive particles, a template or mask is used. However, there are a number of drawbacks to using a layer of adhesive that covers an entire or nearly entire substrate. First, such an amount of adhesive can create inclusions or impurities in the superabrasive particles. Furthermore, there are a number of issues regarding delamination of the template or mask once the abrasive particles have been placed. As a result, some attempts have been made to place adhesive only on those areas of the substrate to which the superabrasive particles are to adhere. However, such methods generally accommodate only groupings of superabrasive particles and not placement of individual superabrasive particles at specified locations or positions.

Therefore, techniques and methods which facilitate the fabrication of superabrasive tools and the growth of superabrasive particles while providing a customized individual particle pattern continue to be sought.

### SUMMARY OF THE INVENTION

Accordingly, the present invention provides a method for arranging and securing individual superabrasive particles on a substrate, at specific locations in accordance with a predetermined pattern. In some aspects, such methods may be employed in preparation for fabricating superabrasive tools or for growing superabrasive particles.

In one aspect, such a method can include applying an array of adhesive droplets onto at least a portion of a substrate in accordance with a predetermined pattern. The adhesive droplets are of a size that allows attachment of only a single abrasive particle, and are of a composition that allows them to remain sufficiently tacky to attach and retain the superabrasive particles despite their small size. Because the distribution of the adhesive droplets is controlled, the particles adhered to them end up assuming the pattern of the adhesive droplets. Thus, the abrasive particles can be disposed in detailed predetermined patterns that can be customized for use in the manufacturing of superabrasive tools or for use in diamond synthesis. Such customization could provide a specific pattern of tool wear or a particular particle growth depending on additional processing that is to be employed. In another aspect, the present invention provides a superabrasive tool or growth precursor having a plurality of superabrasive particles secured to the substrate by a plurality of adhesive droplets as recited herein. Of course, a wide range of materials may be used for the substrate depending on the further process to which the precursor is to be subjected.

In still another aspect of the present invention, superabrasive tools may be made or superabrasive particles may be grown by using the superabrasive tool or growth precursors recited herein.

### BRIEF DESCRIPTION OF THE DRAWINGS

FIG. 1 is a schematic view of an apparatus configured for applying adhesive droplets to a substrate according to one embodiment of the present invention.

FIG. 2 is a schematic view of an apparatus applying adhesive droplets to a substrate, according to another embodiment of the present invention.

FIG. 3 is a schematic view of a substrate having received the adhesive droplets in one embodiment of the present invention.

FIG. 4 is a schematic view of superabrasive particles attached to a substrate via adhesive droplets according to one embodiment of the present invention.

### DETAILED DESCRIPTION

Reference will now be made to exemplary embodiments and specific language will be used herein to describe the same. It will nevertheless be understood that no limitation of the scope of the invention is thereby intended. Alterations and further modifications of the inventive features, process steps, and materials illustrated herein, and additional applications of the principles of the inventions as illustrated herein, which would occur to one skilled in the relevant art and having possession of this disclosure, are to be considered within the scope of the invention. It should also be understood that terminology employed herein is used for the purpose of describing particular embodiments only and is not intended to be limiting.

A. Definitions

In describing and claiming the present invention, the following terminology will be used.

The singular forms “a,” “an,” and “the” include plural referents unless the context clearly dictates otherwise. Thus, for example, reference to “a superabrasive particle” includes reference to one or more of such particles, and reference to “an alloy” includes reference to one or more of such alloys.

As used herein, “particulate” when used with respect to layers indicates that the layer is formed of particulates. Typically, particulate layers of the present invention can be loose powder, packed powder, or compacted powder having substantially no sintered particles. These particulate layers can be porous or semi-porous compacts. Compacted particulate layers can be formed using any known compaction process such as, but not limited to, wet or dry cold compaction such as cold isostatic pressing, die compacting, rolling, injection molding, slip casting, and the like. The particulate materials used in the present invention such as graphite and metal catalyst powders can be preferably handled and stored in an inert environment in order to prevent oxidation and contamination.

As used herein, “metallic” refers to any type of material or compound wherein the majority portion of the material is a metal. As such, various oxide, nitride, and carbide compounds, as well as any other material or compound, containing a greater non-metal portion than metal portion, are not considered to be “non-metallic.” Examples of various metals considered to be particularly useful in the practice of the present invention include, without limitation: aluminum, tungsten, molybdenum, tantalum, zirconium, vanadium, chromium, magnesium, lithium, iron, titanium, beryllium, copper, and alloys thereof. Further, such metals may be treated or otherwise altered, for example “anodized” in order to prevent oxidation or other adverse degradation processes.

As used herein, “abrasive particle,” or “grit,” or similar phrases mean any super hard crystalline, or polycrystalline substance, or mixture of substances and include but are not limited to diamond, polycrystalline diamond (PCD), cubic boron nitride, and polycrystalline cubic boron nitride (PCBN). Further, the terms “abrasive particle,” “grit,” “diamond,” “polycrystalline diamond (PCD),” “cubic boron nitride,” and “polycrystalline cubic boron nitride, (PCBN),” may be used interchangeably.

As used herein, “superhard” and “superabrasive” may be used interchangeably, and refer to a crystalline, or polycrystalline material, or mixture of such materials having a Vicker's hardness of about 4000 Kg/mm² or greater. Such materials may include without limitation, diamond, and cubic boron nitride (cBN), as well as other materials known to those skilled in the art. While superabrasive materials are very inert and thus difficult to form chemical bonds with, it is known that certain reactive elements, such as chromium and titanium are capable of chemically reacting with superabrasive materials at certain temperatures.

As used herein, “diamond” refers to a crystalline structure of carbon atoms bonded to other carbon atoms in a lattice of tetrahedral coordination known as sp³ bonding. Specifically, each carbon atom is surrounded by and bonded to four other carbon atoms, each located on the tip of a regular tetrahedron. Further, the bond length between any two carbon atoms is 1.54 angstroms at ambient temperature conditions, and the angle between any two bonds is 109 degrees, 28 minutes, and 16 seconds although experimental results may vary slightly. The structure and nature of diamond, including its physical and electrical properties are well known in the art.

As used herein, “predetermined pattern” refers to a non-random pattern that is identified prior to construction of a tool, and which individually places or locates each superabrasive particle in a defined relationship with the other diamond particles, and with the configuration of the tool. For example, “positively placing or planting particles in a predetermined pattern” would refer to positioning individual particles at specific non-random and pre-selected positions. Further, such patterns are not limited to uniform grid patterns but may include any number of configurations based on the intended application.

As used herein, “uniform grid pattern” refers to a pattern of diamond particles that are evenly spaced from one another in all directions.

As used herein, “precursor” refers to an assembly of superabrasive particles, substrate or matrix support material, and/or a braze alloy. A precursor describes such an assembly prior to the brazing and/or sintering process, i.e. such as a “green body”.

As used herein, and adhesive “segment” or “droplet” may be used interchangeably, and refer to a discrete mass of adhesive distributed on a substrate. Such segments or droplets may be applied or formed on a substrate in a variety of sizes and patterns, or arrays, and through a variety of mechanisms as described herein.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited.

As an illustration, a numerical range of “about 1 micrometer to about 5 micrometers” should be interpreted to include not only the explicitly recited values of about 1 micrometer to about 5 micrometers, but also include individual values and sub-ranges within the indicated range. Thus, included in this numerical range are individual values such as 2, 3, and 4 and sub-ranges such as from 1-3, from 2-4, and from 3-5, etc. This same principle applies to ranges reciting only one numerical value and should apply regardless of the breadth of the range or the characteristics being described.

The Invention

The present invention encompasses a method for securing superabrasive particles to a substrate in a predetermined pattern. Such a method may include the steps of applying an array of adhesive droplets onto at least a portion of a substrate in accordance with a predetermined pattern and adhering a single superabrasive particle to each adhesive droplet. In accordance with one aspect of the present invention, the adhesive droplets can be placed in a predetermined grid pattern where each adhesive droplet can be of a suitable size and configuration to secure only a single superabrasive particle. A quantity of abrasive particles is then scattered across the substrate. The substrate can then be vibrated, inverted, or otherwise acted upon to remove particles that are not adhered to an adhesive droplet while allowing those particles so adhered to remain in place. In some embodiments, the substrate can be a growth precursor or a tool substrate. In other embodiments, the substrate can simply be a transfer medium, such as a layer or sheet of thin plastic, or other material.

In growth processes it has been discovered that securing superabrasive particles in a predetermined pattern on a growth precursor can help to improve uniformity growth for each particle, nucleation times, and reducing intergrowth of superabrasive particles and non-growing regions. As mentioned above, a typical superabrasive particle growth process includes a growth precursor. Generally, a growth precursor includes suitable raw materials and a particulate catalyst material for growing superabrasive particles. The raw materials can include any materials which are capable of providing growth of a desired superabrasive particle. Such materials can be a carbon source for growing diamond particles, a hexagonal boron nitride source which can be used to form polycrystalline cubic boron nitride, as well as other superabrasive growth materials. Additionally, a particulate catalyst can be used in conjunction with the growth precursor to improve and/or facilitate the superabrasive particle growth. Catalyst materials suitable for superabrasive particle synthesis can include any metal or alloy which is a carbon solvent capable of promoting growth of diamond from carbon source materials. Non-limiting examples of suitable metal catalyst materials can include Fe, Ni, Co, Mn, Cr and alloys thereof. In addition, the catalyst materials under diamond synthesis can include additives which control the growth rate of diamond, i.e. via suppressing carbon diffusion, and also prevent excess nitrogen and/or oxygen from diffusing into the diamond. Suitable additives can include Mg, Ca, Si, Mo, Zr, Ti, V, Nb, Zn, Y, W, Cu, Al, Au, Ag, Pb, B, Ge, In, Sm, and compounds of these materials with C and B.

The superabrasive particles used in a growth processes can any suitable crystalline seed material upon which particle growth can occur. In one aspect of the present invention, the crystalline seeds can be diamond seeds, cBN seeds, or SiC seeds. Typically, the crystalline seeds or superabrasive particles can have a size of about 2 μm to about 500 μm and preferably from about 55 μm to about 100 μm. However, the present invention is ideally suited to patterned placement and growth of almost any size crystalline seed. Allowing for larger crystalline seeds also reduces the growth time required to produce large superabrasive particles. In particular, crystalline seeds suitable for use in the present invention can be larger than typical crystalline seeds, i.e. from about 200 μm to about 500 μm, although the above ranges can also be effectively used. Alternatively, the crystalline seeds can have a size from about 2 μm to about 50 μm, and in some cases from about 20 μm. As a general guideline, typically crystalline seeds can have an average size from about 0.05 to about 0.2 times the average size of the desired grown superabrasive particles. In an additional alternative embodiment, the crystalline seeds can be a mixture of different types of seeds, i.e. two or more of diamond seeds, cBN seeds, and SiC seeds.

In another embodiment, the crystalline seed may be coated with a metal catalyst such as, but not limited to: Fe, Ni, Co, Mn, Cr and alloys thereof. In this case, the small amount of glue used to bind the superabrasive particle does not bind directly to the crystalline seed; therefore, the amount of glue “included” as a contaminant during synthesis in the final diamond product is reduced; providing stronger, higher quality diamonds. Additionally the present embodiment provides the ability to bind small crystalline seeds through large particles. For example, a 20-micron crystalline seed may be nickel wrapped to become a 40-micron particle. This particle is then placed according to the methods outlined in the present invention.

In addition to utilizing the present invention with growth precursors, the present invention can also be used with superabrasive tool fabrication processes. Such superabrasive tools referred to are not limited too, but may include, circular saws, straight blades, gang saws, reciprocating saws, frame saws, wire saws, thin-walled cutoff saws, dicing wheels, and chain saws. Notably, the present invention may be used in conjunction with a tool substrate whereby adhesive droplets are strategically placed on at least one exposed surface of the tool substrate in a predetermined pattern. A typical tool substrate for the fabrication of a superabrasive tool can be a solid, rigid layer formed by a variety of metallic materials. Examples of specific metallic materials include without limitation, cobalt, nickel, iron, copper, carbon, stainless steel, bronze and their alloys and mixtures.

An alternative embodiment of the present invention is a method for temporarily securing individual superabrasive particles to a tool substrate in a predetermined pattern. Typically, a tool substrate has an exposed surface that can be used for bonding superabrasive particles thereto. Previously, many have bonded superabrasive particles to the surface of the substrate in random patterns but only recently it has been discovered that predetermined patterns can affect the particle cutting and wear performance of superabrasive tools. Generally, a tool substrate can be a solid, rigid layers formed from materials such as metallic, ceramic and alloys therefrom. In one embodiment the tool substrate can be comprised of a stainless steel material. Examples of other metallic material can be cobalt, nickel, iron, copper, carbon and their alloys or mixtures. In another embodiment, the tool substrate can be a chemical mechanical planarization (CMP) pad dresser substrate as described in more detail below.

Optionally, superabrasive particles may also be temporarily fixed to a transfer substrate or transfer sheet and then transferred to the tool substrate. In one aspect of this embodiment, the transfer sheet can be made of a metal or plastic, and may be flexible or rigid. The affixing of the superabrasive particles to the surface of the transfer sheet can be accomplished by applying an array of adhesive droplets to the surface by any method described herein. Subsequently the superabrasive particles can be distributed onto the adhesive droplets positioned in a predetermined pattern and the excess particles can be removed therefrom. After placement, the superabrasive particles arranged in a predetermined pattern are transferred to the tool substrate, wherein the tool substrate has a thin coating of an adhesive layer or adhesive droplets placed in substantially the same pattern as the superabrasive particles. For ease of processing, the adhesive droplets or layer disposed on the tool substrate preferably adheres the superabrasive particles more strongly than the adhesive droplets on the transfer substrate.

Placing superabrasive particles in a predetermined pattern on a growth precursor, growth conditions can be optimized to efficiently use available growth volumes, increase crystal quality, and decrease size distribution of grown superabrasive particles. An arrangement that induces uniform particle wear can transfer workload evenly across all particles or can distribute the workload to any region on the substrate depending on the specific tool. For example, a superabrasive particle distribution for the cutting edge of a saw may have a greater distribution of particles on the lead edge and sides than on the middle portion with is generally subjected to less wear. A specific arrangement can also be designed to present a configuration that enhances the grooming performance of a CMP pad dresser. For example, the working surface of the CMP pad dresser may be configured to facilitate the rising of the CMP pad under an interior, or central portion of the dresser, rather than only along an outside or “leading edge” thereof. Such additional rising allows the dresser to more effectively cut into and groom the CMP pad. Along with enhancing the tool performance, transferring the workload can result in extending the service life of the superabrasive tool.

The predetermined pattern can be nearly any patterned desired. In one aspect, the predetermined pattern may be a uniform grid, as shown in FIG. 4. The predetermined pattern can be almost any pattern which places the superabrasive particles at distances suitable for crystal growth or uniform abrasive wear. In one embodiment, the predetermined pattern can be a regular grid pattern of adhesive droplets which can be used to place superabrasive particles at regular intervals in both the x and y directions as shown by the region 22 in FIG. 4. Alternatively, the predetermined pattern can be a series of offset rows. In yet another alternative embodiment, the adhesive droplets can be formed such that varying concentrations of superabrasive particles can be arranged or even varying sizes of particles can be placed on the substrate.

As previously noted, the predetermined pattern can be configured such that a predetermined or uniform distance is maintained between any two adhesive droplets or superabrasive particles adhered thereto. The spacing of the adhesive droplets can vary such that they are substantially uniform or can vary to provide a particular pattern. In one embodiment, the droplets can be formed such that individual superabrasive particles are placed from 400 μm to about 1.5 mm apart. Those skilled in the art will recognize that spacing outside this range can also be used and can depend on the size of the superabrasive particle and the final size of the superabrasive particle after synthesis. It should be noted that these distances are measured from center to center.

As additional guidance, for diamond growth purposes, the droplets can be formed so as to position particles a distance apart which allows each particle sufficient space to receive raw material without competition from neighboring crystals. Depending on the desired final size of the superabrasive particles, the spacing between grown superabrasive particles can range from about 300 μm to about 1000 μm, although distances outside this range can also be used. Typically, the final diameter of the grown superabrasive particles leaves at least a distance of about 0.8 times the final size of the grown superabrasive particles between edges of nearby grown superabrasive particles, and preferably from about 1.5 to about 5 times the final size. For example, a spacing of from about 800 μm to about 900 μm can be used to grow particles having a size of from about 425 μm to about 600 μm (30/40 mesh). In another example, a spacing of about 650 μm can be allowed between grown superabrasive particles having a size of about 45 mesh, while a spacing of about 800 μm can be allowed for larger grown particles of about 35 mesh. In yet another example, a spacing of from about 700 μm to about 1.5 mm can be used to grow 30/40 mesh (600 to 425 μm) grown diamond. Excessively large spacing between droplets can result in significant amounts of wasted space and raw materials, while a droplet spacing which places superabrasive particles too close can result in large numbers of crystals growing together.

Spacing the droplets on a tool substrate can have performance benefiting results, such as aiding in the removal of debris from superabrasive cutting and polishing tools. Additionally, uniform adhesive spacing can allow for uniform wear for superabrasive tools thereby extending the service life of the superabrasive tool. In one embodiment the spacing can be about 0.5 to 5 times the size of an average particle used in the tool substrate or grow precursor fabrication. The size of the adhesive droplets can be about 0.5 to about 50% of the actual size of the superabrasive particle being attached thereto. In another aspect, the size may be up to about 75%. In yet another aspect, the size may be up to 90%, 95%, or 100%. Further, in another embodiment, the spacing between the adhesive droplets can be about 0.5 to about 100%, in some aspects, 0.5 to about 75%, and in yet another aspect, 0.5 to about 50% of the actual adhesive droplet size. Preferably, the adhesive droplet sizes are small enough in size, yet sufficient enough to retain and secure only one particle to each droplet. Accordingly, the size of the droplets will be a function of adhesive tackiness and of the size of the contacting particle.

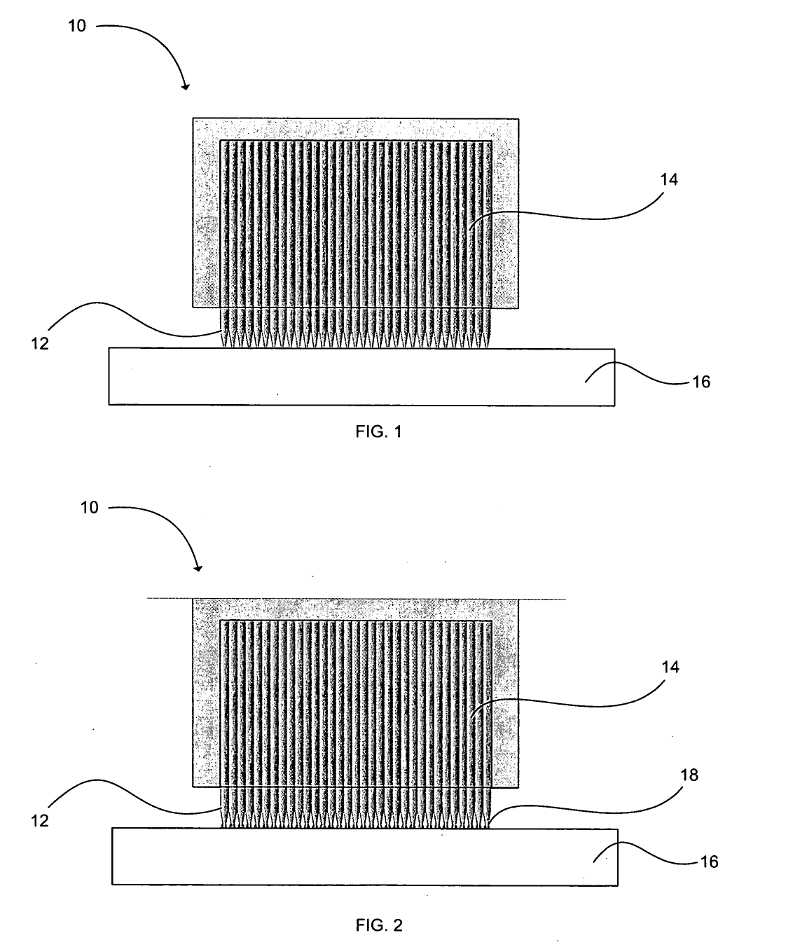

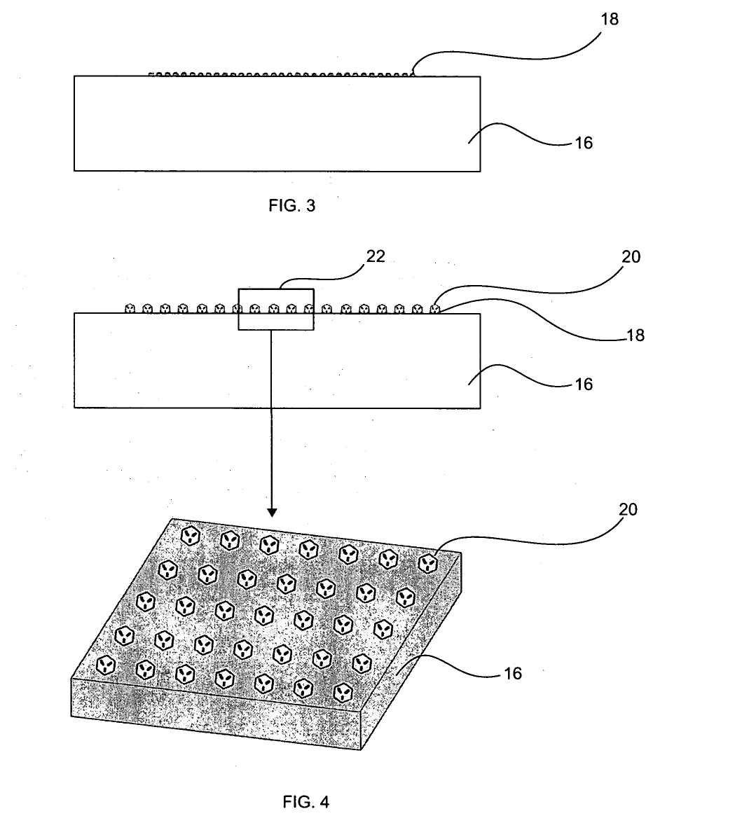

Forming the pattern may be accomplished by various methods. For example, the adhesive droplets may be applied to the substrate by printing, injecting, or dabbing, to name a few. Other methods maybe used without departing from the true spirit of the invention. One novel method is shown in FIG. 1. Referring to FIG. 1, an application tool 10 contains an array of needles or needle type members 14 which may be configured for depositing an array of adhesive droplets to a substrate 16. Generally, the needles are hollow and can contain an adhesive material within the needles. The array of needles may be configured to inject the adhesive through the needles and out onto the substrate in a predetermined amount and size to form the adhesive droplets 18 as shown in FIG. 2 and FIG. 3. The droplets can be sized to accommodate no more than a single superabrasive particle 20 on each adhesive droplet 18. The droplets are typically circular; however any other practical shapes can be used. Typically, the adhesive droplets can have a size range of about 2 μm to about 2 mm. The size can be determined by the size of the superabrasive particle to be attached thereto. In one aspect of the present invention, at least one needle 12 may be configured and used to inject adhesive droplets onto a substrate. In another aspect, an array of needles may be preferred to reduce the droplet application time. In yet another aspect, the array of needles need not be hollow, but may be dipped into an adhesive source. The adhesive can adhere to the needles until the adhesive is dabbed or stamped onto the surface of the substrate. The adhesive source can resemble a sponge or pad that is capable of retaining fluids, similar to an ink pad.

In still another embodiment of the present invention, applying the droplets onto a tool substrate or growth precursor may be accomplished by jet printing or screen printing. Jet printing is a method of jetting a liquid onto a substrate through the use of a jet printer. Typically, a jetting cartridge can contain an acrylic adhesive and can be configured to print a row of adhesive droplets evenly spaced onto the desired substrate. The jet printing method can provide the benefit of accurately spacing the adhesive droplets in a predetermined pattern. In this present embodiment the adhesive may need a solvent to decrease the viscosity of the adhesive to make it less viscous allowing the adhesive to be jetted more efficiently through the nozzle of the jet printer, since a less viscous adhesive could obviate typical jet printing problems such as clogging, splattering, and the like. Also, the tackiness of the adhesive droplet would be extended as the solvent evaporates from the adhesive droplet, allowing application of superabrasive particles at a latter processing time. Furthermore, as the solvent evaporates from the adhesive particle, the adhesive particle size would contract providing a smaller droplet for superabrasive particle attachment. This is important in view of the objective to attach a single superabrasive particle per adhesive droplet. Conversely, in another embodiment, the adhesive can be a two part adhesive where one part can be a resin and the other part an accelerator or an activating agent. Further one part of the adhesive can be jetted from one nozzle of the jetting cartridge and the other from a second nozzle or second jetting cartridge. In this embodiment, plugged nozzles can be minimized separating the resin and accelerator until jetted. In another embodiment, the two part adhesive can be applied by any means disclosed herein, such as rolling, wiping, dabbing, spraying, brushing, screen printing, etc. By using a two part adhesive, the actual adhesive can be mixed, formed and reacted directly to allow bonding onto the substrate. In an alternative embodiment, a first part of the adhesive can be applied to the substrate and the second part of the adhesive can be applied to the abrasive particles, when contact is made the two can react and bond on the substrate.

Alternatively, the adhesive droplets may be formed on the substrate through a screen printing method. Typically, a screen printing method utilizes a template as a screen, wherein a plurality of apertures is formed in a predetermined pattern in the template. The template can then be placed on the substrate and an excess of adhesive can be spread over the template surface such that each of the apertures are filled with adhesive. Once the template is removed from the substrate the adhesive contacted with the substrate will remain on the substrate in the form of a droplet. Following the forming of the droplets superabrasive particles can be sprinkled over the substrate until all the droplets are contacted with a single superabrasive particle.

In one embodiment of the present invention, the adhesive droplets may be formed by applying an adhesive coating to a given substrate and subsequently removing portions of the coating through a removal process leaving the desired amount of adhesive in discrete individual sections, or droplets, at predetermined locations. The removal process could include a removal tool similar to the needle type members (14) in FIG. 1. Specifically, the removal tool could include individual members, as shown in FIG. 1, but that are tapered to a flattened tip, like a flat head screwdriver, to facilitate removal of the adhesive from the substrate. The flattened tip members could be from about 0.001 μm to about 100 um, in another aspect from about 0.01 um to about 10 um, in yet another aspect, from about 0.1 to about 1 um wide and could also be equally distanced apart in proportion to the size of the tip members, or could be spaced apart by a desired factor such as 5, 10, 50, or 100, etc. the size of the tip members. Depending on the tip width and the distance between the tip members, a number of predetermined patterns could be produced after the removal process. The removal process could be simply contacting the removal tool to the substrate, and then subsequently moving the tool straight across the substrate, displacing the adhesive from the substrate by the flattened tip members. Performing the removal process on the substrate twice, perpendicular to each other, could provide an equally-spaced, predetermined grid pattern that could be further used for diamond placement as outlined in the methods of the present invention. Again, droplets formed in this manner will typically only be large enough to adhere a single diamond particle to each droplet.

As noted above, the adhesive droplets should be carefully sized so as to minimize the amount of adhesive that contacts the superabrasive particle, thereby limiting the risk of developing an inclusion or flaw in the superabrasive particle. However, most common adhesives will vaporize at temperatures above about 400° C. and do not chemically react with the braze alloy or superabrasive particles.

The adhesive used in accordance with the present invention can be an organic binder. Typical adhesives or binders include polyvinyl alcohol (PVA), polyvinyl butyral (PVB), polyethylene glycol (PEG), paraffin, phenolic resin, wax emulsions, and acrylic resins. Typical binder solvents include methanol, ethanol, acetone, trichlorethylene, toluene, etc. Typical plasticizers are polyethylene glycol, diethyl oxalate, triethylene glycol dihydroabietate, glycerin, octyl phthalate. In one specific example, an acrylic adhesive can be diluted with a solvent such as acetone and then applied via an array of needles, on the growth precursor or tool substrate. Preferably, the adhesive should be configured to remain tacky for a sufficient amount of time prior to adhering the superabrasive particles to each adhesive droplet. This can be accomplished by including a sufficient amount of solvent in with the adhesive. The adhesive used should also provide sufficient adhesion strength to secure only one superabrasive particle to the substrate. The adhesion can also provide sufficient strength to securely maintain the particles in positioned in the current configuration during transportation of the substrate. In one embodiment, the adhesive droplets can have a viscosity of less than about 500,000 cP. In another embodiment, the viscosity can be of from about 5 cP to about 100,000 cP. In yet another embodiment, the viscosity can be of from about 5 cP to about 50,000 cP. In still yet another embodiment, the viscosity can be of from about 5 cP to about 10,000 cP.

Disposing the superabrasive particles to the applied adhesive droplets can be accomplished by varying methods. Mainly, the superabrasive particles are sprinkled in excess over the substrate and adhesive droplets. Once every adhesive droplet receives a superabrasive particle the remaining particles can be removed from the substrate. In another embodiment, the superabrasive particles can be disposed onto the adhesive droplets by means of a screen template. Particularly, a template having a plurality of apertures, wherein the apertures consist of a uniform size and pattern can be used to adhere particles of a particular size to the substrate. Alternatively, when disposing particles of such small sizes, an anti-static material can be coated over the particles to prevent them from sticking together through static forces. This can ensure that only one particle is attached to only one droplet.

In another embodiment, the superabrasive particles can be uniformly scattered onto the substrate by an automatic vibration feeder, which uses vibrational forces to help counteract electrostatic attractions between superabrasive particles. A vibration feeder can use a variety of a vibrational sieve meshes. Vibrational sieve meshes can control the size of the particles to be scattered. Additionally, more than one layer of sieves can be used. For example, for 30-micron superabrasive particles, 200 mesh (75 microns) may be used as the upper sieve; and 400 mesh (37 microns) as the lower sieve, effectively separating larger superabrasive particles from the mixture. The remaining 30-micron superabrasive particles will shower down uniformly onto the adhesive droplets laying underneath. By providing adequate shower time, the substrate will be covered with at least one layer of diamond seeds.

Subsequent to receiving the superabrasive particles, the prepared precursor may be subjected to desired further processing. In the case of both growth precursors and tool precursor, the assembled substrate and adhered particles can then be subjected to pressure and temperature conditions sufficient to grow or permanently bond superabrasive particles to the substrate.

The following examples illustrate exemplary embodiments of the invention only and are not to be considered limiting.

### EXAMPLES

### Example 1

Diamond crystals with faceted morphology or blocky shape having a size from 20-30 microns are coated with nickel via an electrolysis process to a size of 60-70 microns. Purified natural graphite powder having a grain size of about 20 microns are mixed with INVAR (Fe65-Ni35) powder having a size of about 40 microns at a weight ratio of 1:1. The mixture is then pressed at about 200 MPa to form disks of 0.9 mm in thickness of various diameters, e.g. 37 mm, 61 mm, and 85 mm. An array of adhesive droplets can be screen printed onto an exposed surface of the disks to form a predetermined pattern. Diamond seeds are sprinkled onto the adhesive such that only one diamond seed contacted a single adhesive droplet. The remaining or unattached diamond particles are removed from the substrate.

After removal of excess diamond crystals, the diamond grid formed on the adhesive droplets is removed from the backing layer and glued to the pressed graphite-metal disks. The gluing may be on the back side of the adhesive pad opposite the diamond seeds or on the same side where diamond seeds are attached. Multiple layers (e.g. 40) of graphite-metal disks and patterned diamond seeds are stacked up in a steel container having a wall thickness of about 0.2 mm to form a multilayered precursor assembly. The precursor assembly is heat treated under vacuum (10⁻³ torr) at 1000° C. for 60 minutes with intermittent hydrogen purges. During cooling the stacks are purged under nitrogen gas.

The pretreated stacks are compressed at about 300 MPa to form cells for ultrahigh pressure synthesis of diamond. Subsequently, the pretreated stacks are pressed at 5.2 GPa and heated to 1300° C. for 45 minutes. The grown diamonds are recovered and examined. The diamond seeds are grown to about 500 microns (30/40 mesh) with uniform size and similar shape. These diamond crystals are grown with high crystal perfection and mechanical strength. The yield of diamond is over 4 carats per cubic centimeter.

### Example 2

The same conditions and steps are performed as in Example 1 with INVAR powder being replaced by pure Fe and Ni powder (about 6 microns) at a 2:1 weight ratio. The resulting grown diamond can be of substantially the same quality and sizes.

### Example 3

The same conditions and steps are performed as in Example 1 except that the heating time is extended to one hour so the diamond size increased to over 600 microns (25/30 mesh). Also, the diamond yield is over 5 carats/cubic centimeter with similar quality as in Example 2.

The above description and examples are intended only to illustrate certain potential embodiments of this invention. It will be readily understood by those skilled in the art that the present invention is susceptible of a broad utility and applications. Many embodiments and adaptations of the present invention other than those herein described, as well as many variations, modifications and equivalent arrangements will be apparent from or reasonably suggested by the present invention and the forgoing description thereof without departing from the substance or scope of the present invention.

Accordingly, while the present invention has been described herein in detail in relation to its preferred embodiment, it is to be understood that this disclosure is only illustrative and exemplary of the present invention and is made merely for purpose of providing a full and enabling disclosure of the invention. The foregoing disclosure is not intended or to be construed to limit the present invention or otherwise to exclude any such other embodiment, adaptations, variations, modifications and equivalent arrangements, the present invention being limited only by the claims appended hereto and the equivalents thereof.

What is claimed is:

1. A method of temporarily securing individual superabrasive particles to a substrate in a predetermined pattern, comprising the steps of:
forming an array of discrete adhesive segments onto at least a portion of a substrate in accordance with a predetermined pattern, said adhesive segments being suitable to each secure only a single superabrasive particle; and
adhering superabrasive particles to the adhesive segments.

2. The method of claim 1, wherein the adhesive is a composition that remains tacky for a sufficient amount of time to allow the superabrasive particles to adhere to each adhesive droplet.

3. The method of claim 2, wherein the adhesive has a viscosity less than about 500,000 cP.

4. The method of claim 1, wherein the superabrasive particles have a size of about 2 mm or less.

5. The method of claim 1, wherein the superabrasive particles have a size of about 2 μm to about 500 μm.

6. The method of claim 1, wherein the superabrasive particles have a size of about 500 μm to about 1 mm.

7. The method of claim 1, wherein the substrate is either a tool substrate or a growth precursor.

8. The method of claim 1, wherein the substrate is transfer sheet.

9. The method of claim 8, wherein the transfer sheet is a flexible backing film.

10. The method of claim 7, wherein the substrate is a growth precursor and the superabrasive particles have a size of about 2 μm to about 500 μm.

11. The method of claim 7, wherein the substrate is a tool substrate and the superabrasive particles have a size of about 500 μm to about 1 mm.

12. The method of claim 7, wherein the tool substrate is formed from a material selected from the group consisting of nickel, tungsten, tungsten carbide, stainless steel and combinations thereof.

13. The method of claim 7, wherein the growth precursor includes a raw material and a particulate catalyst material.

14. The method of claim 13, wherein the raw material is a carbon source.

15. The method of claim 14, wherein the carbon source is graphite.

16. The method of claim 13, wherein the catalyst material is a member selected from the group consisting of Fe, Ni, Co, Mn, Cr, and alloys thereof.

17. The method to claim 1, wherein the discrete adhesive segments have a size of about 2 mm or less.

18. The method of claim 1, wherein the adhesive provides sufficient adhesion strength to secure a single superabrasive particle to the substrate during transport of the substrate.

19. The method of claim 1, wherein the adhesive is an organic binder selected from the group consisting of acrylic adhesive, wax, polyethylene glycol, polyvinyl alcohol, paraffin, naphthalene, polyvinyl butyral, phenolic resin, wax emulsion, and mixtures thereof.

20. The method of claim 19, wherein the organic binder is an acrylic adhesive.

21. The method of claim 1, wherein said superabrasive particles are selected from diamond, diamond-like carbon, polycrystalline diamond (PCD), cubic boron nitride (cBN), and polycrystalline cubic boron nitride (PCBN).

22. The method of claim 1, wherein the superabrasive particles are crystalline seeds.

23. The method of claim 1, wherein the superabrasive particles are coated with an anti-static material.

24. The method of claim 1, wherein the superabrasive particles are coated with a catalyst metal.

25. The method of claim 24, wherein the catalyst metal is selected from the group consisting of Fe, Ni, Co, and alloys thereof.

26. The method of claim 1, wherein the predetermined pattern is a grid.

27. The method of claim 1, wherein the predetermined pattern of the superabrasive particles is configured such that a predetermined distance is maintained between any two superabrasive particles.

28. The method of claim 27, wherein the predetermined distance is from about 1.5 to about 5 times the size of the individual particles.

29. The method of claim 1, wherein the step of forming comprises printing, injecting or dabbing the adhesive segments onto at least a portion of the substrate.

30. The method of claim 29, wherein said printing includes jet printing and screen printing.

31. The method of claim 29, wherein said injecting comprises injecting through at least one needle a predetermined amount of adhesive onto at least a portion of the substrate.

32. The method of claim 29, wherein dabbing includes dipping an array of needles into an adhesive source and dabbing a predetermined amount of adhesive onto at least a portion of the substrate.

33. The method of claim 1, wherein the step of forming comprises the steps of:
applying an adhesive coating to the substrate; and
removing portions of the adhesive coating with a removal tool.

34. The method of claim 33, wherein the removal tool is formed from needle type members that are tapered to a flattened tip allowing removal of portions of the adhesive by contacting the flattened tip members to the surface of the substrate with sufficient force such that as the removal tool is moved across the substrate, the adhesive is displaced by the flattened tip members.

35. The method of claim 34, wherein the removal tool flattened tip members are from about 0.001 um to about 100 um wide and are equally distanced apart by a factor of from about 1 to about 10 times the size of each tip member.

36. A superabrasive tool precursor having a plurality of superabrasive particles secured thereto by a plurality of adhesive segments as recited in claim 1.

37. A method of making a superabrasive tool, comprising the step of:
a) providing a superabrasive tool precursor as recited in claim 36; and
b) subjecting the tool precursor to pressure and temperature conditions sufficient to bond the superabrasive particles to the tool substrate.

38. A superabrasive particle growth precursor having a plurality of superabrasive particles secured thereto by a plurality of adhesive segments as recited in claim 1.

39. A method of growing superabrasive particles, comprising the steps of:
a) providing a growth precursor as recited in claim 38; and
b) subjecting the growth precursor under temperature and pressure conditions sufficient to grow superabrasive particles.
